(19) United States
(12) Patent Application Publication
(10) Pub. No.: US 2010/0072485 A1
(43) Pub. Date: Mar. 25, 2010

(54) SEMICONDUCTOR DEVICE AND SEMICONDUCTOR MANUFACTURING METHOD

(75) Inventors: Jun Suda, Kyoto (JP); Tsunenobu Kimoto, Kyoto (JP)

Correspondence Address: Juan Carlos A. Marquez;c/o Stites & Harbison PLLC, 1199 North Fairfax Street, Suite 900, Alexandria, VA, 22314-1437, US

(73) Assignee: Kyoto University

(21) Appl. No.: 12/450,424

(22) PCT Filed: Mar. 25, 2008
(86) PCT No.: PCT/JP2008/055488

§ 371 Date: Sep. 25, 2009

(30) Foreign Application Priority Data
Mar. 26, 2007 (JP) 2007-080243

(51) Int. Cl. H01L 29/24; G02B 6/10

(52) U.S. Cl. 257/77; 385/130; 257/E29.104

(57) ABSTRACT

One atomic layer of Si atoms 3 is grown on an Si-terminated SiC surface 1a having an Si polar face, and one atomic layer of C atoms 5 is further grown thereon. Then, Si and C are supplied to form an SiC layer. The surface of the SiC layer thus grown is a C polar face opposite to the Si polar face. That is, according to the above-described step, it is possible to grow an SiC polarity-reversed layer 1x having a C polarity on an SiC layer 1 having an Si polarity, with one atomic layer of an Si intermediate layer b interposed therebetween. Consequently, it is possible to provide a technique to reverse the polarity of SiC on the surface.

### TECHNICAL FIELD

The present invention relates to a semiconductor device and, more particularly, to a polarity control technique used for a semiconductor device formed on an SiC layer.

### BACKGROUND ART

SiC has extremely high thermal conductivity, and an electrically conductive substrate and an electrically insulating substrate made of SiC are available. In addition, SiC is characterized by being close in lattice constant and thermal expansion coefficient to AlN and GaN-based group III nitrides, and by having polarities like the group III nitrides. A study is being made actively, in order to realize high-performance light-emitting diodes, laser diodes, transistors, optoelectronic integrated devices, and the like that utilize one or both of a group III nitride and SiC by growing a high-quality AlN or GaN-based group III nitride on an SiC substrate. SiC is also relatively close in lattice constant to ZnO-based materials which are group II oxides. Hence, a study is being made to apply SiC also as a group II oxide substrate.

SiC and a group III nitride are characterized in that Si-N bonds and C-group III metal (Al or Ga) bonds formed therebetween are strong. Consequently, SiC has the nature that the polarity control of a group III nitride grown on an SiC substrate is possible. That is, Si and N combines with each other in an SiC (0001) Si polar face in which the bonding hands of Si perpendicularly project to the surface thereof. As a result, the grown group III nitride has a structure in which bonds of group III atoms project perpendicularly, i.e., has a group III polar face. Conversely, C and a group III metal combine with each other in an SiC (000-1) C polar face in which the bonding hands of C perpendicularly project to the surface thereof. As a result, the grown group III nitride has a structure in which bonds of nitrogen atoms perpendicularly project, i.e., has an N (nitrogen) polar face. The same holds true for a group II oxide. That is, since an Si—O bond is strong, a group II polar face grows on the Si polar face and a group II oxide having an O polar face grows on the C polar face.

In an ordinary device, crystal polarities (or orientations) are desirably unified into one polarity across the entire surface of a substrate. However, in a certain type of device, for example, a second-order harmonic generation element which is one of nonlinear optical elements, regions in which a polarity is periodically reversed in the traveling direction of light are artificially introduced, thereby achieving quasi-phase matching and realizing extremely superior characteristics. In addition, if the characteristics of a device, such as the threshold voltage of a field-effect transistor, can be controlled by the polarity of a surface and an opposite polarity can be made to coexist in the surface, it is possible to use two types of transistors having significantly different threshold voltages. Consequently, the freedom of integrated circuit design improves greatly. These devices and integrated circuits cannot be fabricated, however, if polarities are unified into one polarity within a substrate plane.

Non-patent document 1: Chowdhury A, Ng H M, Bhardwaj M, et al. “Second-harmonic generation in periodically poled GaN” APPLIED PHYSICS LETTERS 83 (6): 1077-1079 AUGUST 11 (2003).

### DISCLOSURE OF THE INVENTION

### Problems to be Solved by the Invention

On a substrate made of sapphire having no polarities unlike SiC, there is fabricated a polarity-reversed structure by taking advantage of the polarity of an obtained group III nitride being different depending on growth conditions or the surface treatment conditions of the substrate. That is, the group III nitride is first grown under growth conditions whereby the nitride has a Ga polarity, and then a group III nitride having a Ga polarity is removed by etching away unnecessary portions of the group III nitride, thereby exposing the sapphire substrate. Next, the group III nitride is grown under growth conditions whereby an opposite N polarity is formed. Thus, it is possible to grow a group III nitride having an opposite N polarity in a portion where the sapphire substrate is exposed (a group III nitride having a Ga polarity grows in a portion where the group III nitride having a Ga polarity has already been formed, while inheriting the polarity of the underlying group III nitride). As a result, a structure in which a group III nitride having an opposite polarity is mixed in can be artificially formed on a substrate surface. Such an artificially polarity-reversed structure, in which the substrate itself is nonpolar, can be realized on a sapphire substrate where the polarity of a group III nitride that grows thereon can be selected depending on growth conditions. In the case of a substrate made of SiC, however, it is not possible to adopt this method since the polarity of the group III nitride that grows on the substrate is fixed by the polarity of the substrate, as described above.

An object of the present invention is to provide a technique to form an SiC layer having a polarity opposite to the polarity of an SiC substrate, a group III nitride layer, or a group II oxide on a surface of the SiC substrate, thereby allowing the SiC layer having an opposite polarity, the group III nitride layer, and the group II oxide layer to coexist on the SiC substrate.

### Means for Solving the Problems

In the (0001) Si polar face of 4H-, 6H- or 15R-SiC (a (111) Si polar face in the case of 3C-SiC), the bonding hands of Si perpendicularly project to a surface. If one atomic layer (referred to as an “intermediate layer”) of Si is grown on this Si polar face of SiC, Si—Si bonds are formed. As a result, it is possible to realize a surface structure in which Si bonds obliquely project out of the surface. By combining carbon with this surface structure, the carbon is caused to combine with three Si bonding hands. Consequently, the surface structure is formed into a surface equivalent to the C polar face of SiC in which the bonding hands of carbon project perpendicularly. By continuing SiC growth on this surface, it is possible to form an SiC layer having an oppositely-polarized C polar face on the Si polar face of SiC through the intermediate layer. In addition, by growing a group III nitride or a group II oxide on this C polar face of SiC using a usual method, it is possible to grow a group III nitride having an N polar face or a group II oxide having an O polar face.

By combining nitrogen with the surface structure in which Si—Si bonds are formed and consequently Si bonds obliquely project out of the surface, the nitrogen is caused to combine with three Si bonding hands. Consequently, the surface structure is formed into a surface equivalent to the N polar face of the group III nitride in which the bonding hands of nitrogen project perpendicularly. If a group III nitride is grown on this surface, the nitride grows with an N polar face retained. Thus, it is possible to obtain a group III nitride having an N polar face the polarity of which is opposite to a polarity expected in usual growth on SiC having an Si polar face.

By combining oxygen with the surface structure in which Si—Si bonds are formed and consequently Si bonds obliquely project out of the surface, the oxygen is caused to combine with three Si bonding hands. Consequently, the surface structure is formed into a surface equivalent to the O polar face of the group II oxide in which the bonding hands of oxygen project perpendicularly. If a group II oxide is grown on this surface, the oxide grows with an O polar face retained. Thus, it is possible to obtain a group II oxide having an O polar face the polarity of which is opposite to a polarity expected in usual growth on SiC having an Si polar face.

In principle, polarity reversal takes place as long as the number of Si insertion layers is an odd number and, therefore, it is possible to use an arbitrary odd number of Si intermediate layers. Due to a large lattice mismatch between Si and SiC, however, defects attributable to the lattice mismatch occur if an Si intermediate layer thicker than necessary is introduced. Consequently, the crystallinity of a polarity-reversed layer formed on the intermediate layer degrades. In addition, if the thickness of the Si intermediate layer increases depending on growth conditions, Si does not grow in a layer-shaped manner but grows in an island-shaped manner. Care should therefore be exercised since there arises the problem of inability to control the number of Si layers for the substrate as a whole (the thickness increases more largely in island-shaped portions than in layer-shaped portions, that is, thicknesses, i.e., polarities cannot be unified within a plane).

As an alternative, Si of an intermediate layer is intentionally grown thick, in order to cause polarity information held by SiC to disappear in the vicinity of the surface of the layer, thereby placing the layer in a state of as if being equivalent to the (111) face of Si having no polarities. Then, by controlling the growth conditions of SiC, a group III nitride or a group II oxide on the Si(111) face, it is possible to adopt a method for growing layers having arbitrary polarities. In this case, there is no need to strictly control the number of Si layers and, therefore, it is possible to simplify the process of forming intermediate layers. This means, however, that polarities are controlled by the growth conditions of the SiC, the group III nitride or the group II oxide. Accordingly, there is the possibility that some regions having a polarity opposite to an intended polarity mixes with the intermediate layer. In addition, the crystallinity of Si formed thick on SiC as described above cannot be said to be satisfactory for reasons of lattice mismatch. Thus, the quality of a crystal grown on this thick Si is sacrificed. The intermediate layer can be used with no difficulty for the fabrication of a device, such as a nonlinear optical element, insensitive to crystallinity. The intermediate layer is somewhat unsuitable, however, for such devices as a light-emitting diode, the crystallinity of which cause remarkable effects on the performance thereof.

As the intermediate layer, it is possible to use a material consisting primarily of a group IV element, having excellent affinity for SiC which is a group IV-IV compound, and having no polarities, i.e., a material consisting primarily of Si, Ge, C or the like. Use of pure Si is desirable from the viewpoint of simplifying film-forming apparatus. It is also possible, however, to use mixed crystals, such as SixGel-x with which Ge or the like is mixed, in order to facilitate the laminar growth of an intermediate layer. Since the better the crystallinity of an intermediate layer is, the better the quality of a polarity-reversed layer in an upper portion of the intermediate layer can be made, a composition or a thickness, whereby the best crystallinity can be obtained, may be selected according to a film-forming method. It is also possible to perform n-type doping, p-type doping, or the like, in order to provide the intermediate layer with a conductive property. Although in the description given above, an explanation has been made by taking, as an example, reversal from an Si polar face to a C polar face (or to an N polar face or an O polar face) by an Si intermediate layer, completely the same logic holds true with a C intermediate layer and a C polar face. Thus, there is obtained a total of four variations of reversal.

### Advantages of the Invention

According to the present invention, it is possible to fabricate a structure including polarity-reversed regions within a plane and comprised of SiC, a group III nitride and a group II oxide on an SiC polar face, with ease and precision. The present invention is applicable to a wide variety of fields, including, in particular, a quasi-phase matched nonlinear optical device and a field-effect transistor integrated circuit based on a group III nitride and a group II oxide.

### BRIEF DESCRIPTION OF THE DRAWINGS

FIGS. 1(A) to (C) are diagrams concerning the polarities of SiC.

FIG. 2 is a diagram illustrating a method for growing an SiC semiconductor crystal in accordance with a first embodiment of the present invention, as well as illustrating a near-surface crystal structure in each growth process.

FIG. 3 is a diagram illustrating a near-surface crystal structure of an SiC semiconductor crystal in accordance with the present embodiment.

FIG. 4 is a diagram illustrating a crystal structure related to a state in which Si is excessively adsorbed.

FIG. 5 is a diagram illustrating a semiconductor growth method according to a first modified example of the first embodiment of the present invention.

FIGS. 6(A) to 6(C) are diagrams illustrating a method for growing a SiC semiconductor crystal in accordance with a second embodiment of the present invention.

FIG. 7 is a diagram illustrating a semiconductor growth method according to modified examples of the first and second embodiments of the present invention.

FIG. 8 is a simplified process diagram illustrating a semiconductor device and a manufacturing method thereof in accordance with a third embodiment of the present invention.

FIG. 9 is a simplified process diagram illustrating a method for manufacturing a semiconductor device in accordance with a fourth embodiment of the present invention.

FIG. 10 is a simplified process diagram illustrating a semiconductor device and a manufacturing method thereof in accordance with a fifth embodiment of the present invention.

FIG. 11(A) illustrates an SiC polarization reversal structure fabricated in the third embodiment, whereas FIG. 11(B) illustrates a polarization reversal structure comprised of a group III nitride or a group II oxide formed by growing an arbitrary group III nitride or group II oxide, such as AlN, on the structure of FIG. 11(A).

FIG. 12 illustrates, as a technology according to a sixth embodiment of the present invention, a semiconductor device fabricated by applying the aforementioned fourth embodiment and having a waveform conversion function, wherein FIGS. 12(A) to 12(D) are diagrams illustrating an example of steps of fabricating a quasi-phase matched wavelength conversion element having a periodically space-reversed structure.

FIG. 13(A) is a perspective view of FIG. 12(C), whereas FIG. 13(B) is a cross-sectional view of FIG. 12(D).

FIG. 14 illustrates a seventh embodiment of the present invention, wherein FIGS. 14(A) to 14(D) diagrams illustrate a procedure for fabricating a GaN-based high electron mobility transistor(HEMT) integrated circuit in accordance with the present embodiment.

FIG. 15 is a cross-sectional view illustrating a structure in which two types of HEMTs fabricated by the steps of FIG. 14 are monolithically integrated.

FIG. 16 is a diagram illustrating a modified example of the seventh embodiment of the present invention, wherein an SiC device (nMOSFET) is located in a polarity-unreversed region and a group III nitride device (HEMT) is located in a polarity-reversed region.

FIG. 17 is a diagram illustrating a structure in which an SiC MOSFET including polarity-reversed SiC provided through an intermediate layer is formed in place of the HEMT illustrated in FIG. 16, along with the SiC MOSFET illustrated in FIG. 16.

### DESCRIPTION OF SYMBOLS

1: SiC substrate, 1b: Intermediate layer, 1e: C atom layer, 1x: SiC layer, 3: Si atom, 5: C atom, 23b: Polarity-reversed layer, 23a: Polarity-unreversed layer.

### BEST MODE FOR CARRYING OUT THE INVENTION

Hereinafter, an explanation will be made of a semiconductor technology in accordance with embodiments of the present invention while referring to the accompanying drawings.

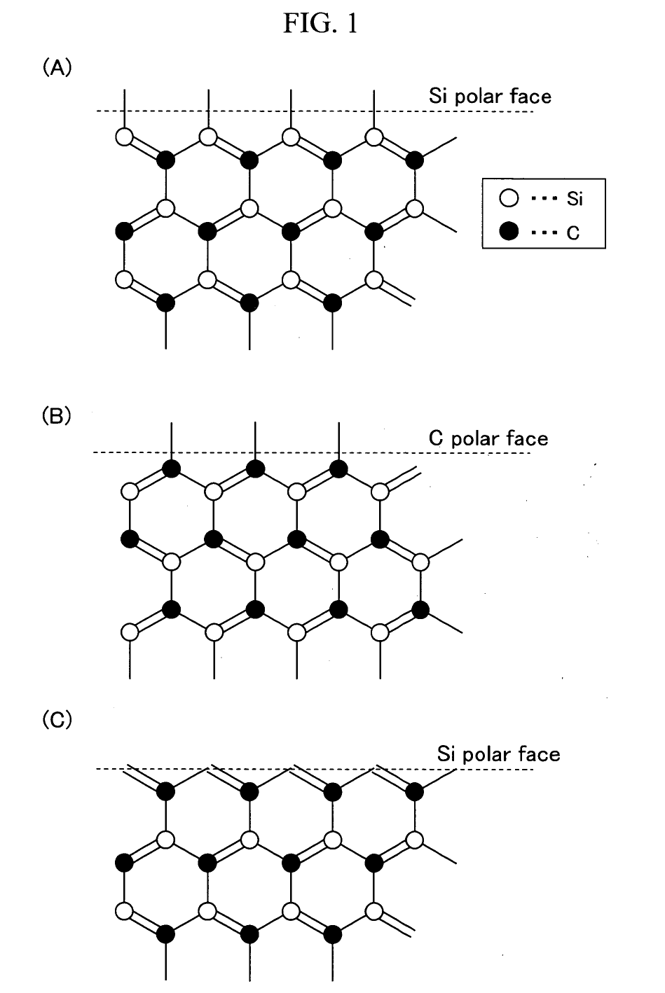

First, an explanation will be made of a semiconductor device and a semiconductor manufacturing method in accordance with a first embodiment of the present invention. FIGS. 1(A) and 1(B) are diagrams concerning the polarities of SiC. As illustrated in FIG. 1(A), the polarity of a crystal is defined depending on which bonding hands (denoted by solid lines), either those of Si atoms (denoted by outline circles) or those of C atoms (denoted by filled circles), extend from a crystal surface (denoted by a dotted line) in a direction perpendicular thereto. In the structure illustrated in FIG. 1(A), bonding hands of Si extend perpendicularly from the surface denoted by a dotted line, and this surface is referred to as an Si polar face or a (0001) face. On the other hand, in the structure illustrated in FIG. 1(B), bonding hands of C extend perpendicularly from a surface denoted by a dotted line, and this surface is referred to as a C polar face or a (000-1) face. Note however that even in the case of an Si polar face, the uppermost surface is terminated with C atoms, as illustrated in FIG. 1(C), if SiC growth is ended with, for example, the deposition of C. Nonetheless, bonding hands of Si extend toward the uppermost surface if attention is paid to Si atoms one layer of atoms lower than the surface. Thus, the surface is still an Si polar face in this case.

Strictly speaking, polar faces refer to the (0001) face and the (000-1) face only. However, a face inclined several degrees from the (0001) face, for example, can be regarded as an Si polar face. Even in the case of a face, such as a (03-38) face or a (0-33-8) face, inclined several tens of degrees from the (0001) face or the (000-1) face, the former is closer to the (0001) face which is an Si polar face and the latter is closer to the (000-1) face which is a C polar face. Accordingly, in the present specification, these faces are also included in the aforementioned polar faces as polar faces in a broad sense. A face opposite in polarity to the (0001) face is referred to as the (000-1) face, and a face opposite in polarity to a face inclined certain degrees from the (0001) face is referred to as a face inclined at a certain angle from the (000-1) face.

On the other hand, faces, such as (11-20) and (1-100) faces, completely perpendicular to the (0001) face are nonpolar faces for which polarities cannot be defined. These faces are therefore not referred to in the present specification.

As described above, since a bond between Si and N and a bond between C and a group III metal are strong, Si combines with N on an Si polar face if a group III nitride is grown on SiC. The group III nitride thus grown consequently has a structure in which bonding hands of group III atoms project perpendicularly. That is, the group III nitride has a group III polar face. In the present specification, the group III polar face is referred to as an identical polarity in contrast to an Si polar face, and an N polar face is referred to as an opposite polarity. Likewise, for a group II oxide, the group II polar face is referred to as an identical polarity in contrast to an Si polar face, and an O polar face is referred to as an opposite polarity.

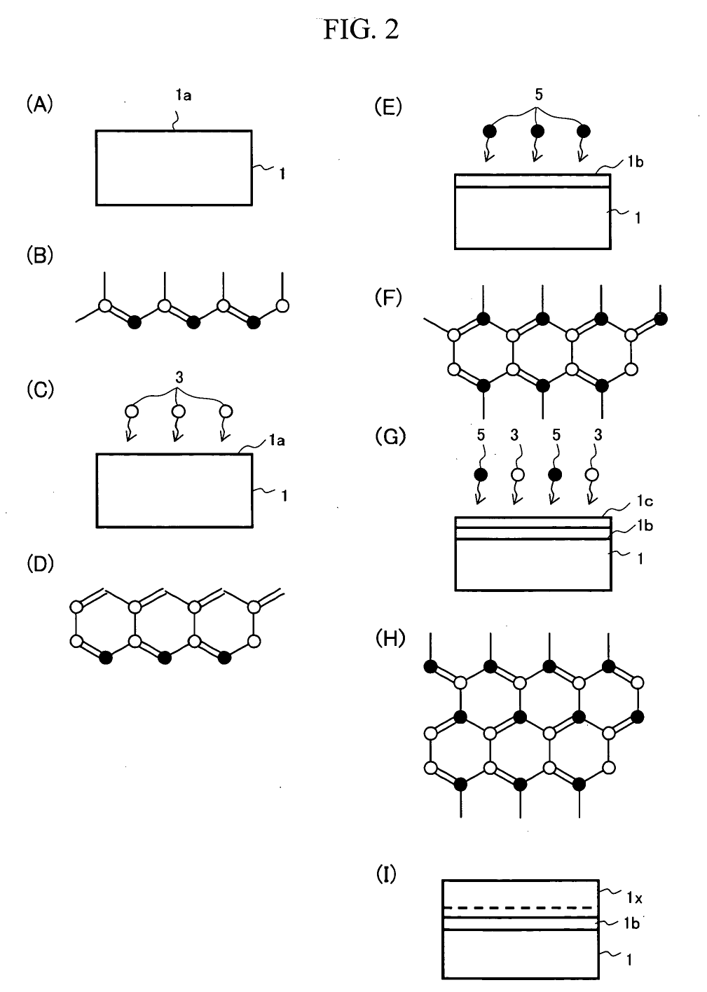

FIGS. 2(A) to 2(I) are diagrams illustrating a method for growing a SiC semiconductor crystal in accordance with the present embodiment.

First, an SiC substrate 1 having a (0001) Si polar face is prepared, and a surface treatment for the substrate to have a clean surface is performed. As illustrated in FIG. 2(A), a surface 1a of the SiC substrate 1 is in the state that bonding hands project perpendicularly from Si atoms, as illustrated in FIG. 2(B). In this state, an odd number of layers of Si atoms 3 (one layer is shown by way of example in the figure) are laminated. Consequently, as illustrated in FIGS. 2(D) and 2(E), Si—Si bonds (intermediate layer) 1b are formed on the surface 1a. These Si—Si bonds are unstable on the surface but can be maintained if they are in a nonequilibrium state. Note that it is preferable to precisely laminate an odd number of atomic layers from the viewpoint of not introducing defects or the like. However, even if such an amount of Si raw material as, for example, a 0.1 atomic layer or so is oversupplied, portions where Si atoms form an even number of layers account for only approximately 10% of the total within a plane. In addition, these portions are covered over by subsequent lateral growth or the like. Thus, the objective of polarity reversal is attained.

Next, as illustrated in FIGS. 2(E) and (F), one atomic layer of C atoms 5 is grown on the SiC substrate 1 in which the intermediate layer 1b is formed. On the outermost surface, there is formed a C atom layer 1c, as illustrated in FIG. 2(G). After that, Si and C are supplied in the same way as in usual SiC growth to form an SiC layer 1x, as illustrated in FIGS. 2(G) and 2(H). At this time, the outermost surface of the grown SiC layer 1x becomes a C polar face different from an Si polar face. When the SiC layer 1x is made to continue growing further, an SiC layer having a C polar face grows. According to the above-described steps, as illustrated in FIG. 2(I), it is possible to grow a polarity-reversed SiC layer x having a C polarity on an SiC layer 1 having an Si polarity, with one atomic layer of the Si intermediate layer 1b interposed therebetween. Note that the one carbon atomic layer denoted by reference symbol 1c can be regarded as one of layers constituting the SiC layer 1x of C polarity on the carbon atomic layer.

In the above-described growth steps, it is important to precisely control the thickness of the Si intermediate layer 1b on the SiC surface 1a, so that the intermediate layer is formed of an odd number of layers. Accordingly, it is preferable to perform growth using surface-sensitive measuring means, such as electron beam diffraction, X-ray photoemission spectroscopy (XPS), or Auger electron spectroscopy, in the process of depositing the intermediate layer 1b, while observing a surface coverage and the like in real time. Note that, once conditions are fixed, it is possible to precisely deposit an intermediate layer composed of an odd number of atomic layers by controlling a supply rate and a supply time, without conducting real-time observations by these means.

In addition, since the intermediate layer 1b is thermodynamically unstable in initial stages of its growth and the subsequent growth of SiC, the intermediate layer needs to be grown in a state of being off from thermal equilibrium. A molecular beam epitaxy (MBE) method is one of the optimum methods in the sense that a nonequilibrium state is realized and the above-described real-time observation is possible. Considering mass productivity and the like, however, a vapor-phase epitaxy (VPE) method is also an effective method, though not capable of real-time observation. In layer growth on the intermediate layer 1b, it is important to set temperature lower than the usual growth temperature of SiC, in order to prevent atomic exchange or diffusion from occurring in the vicinity of a surface. For example, if the temperature of a step of supplying C onto Si—Si bonds is too high, Si switches positions with C in the surface, i.e., the Si intermediate layer 1b is carbonized, and SiC having a polarity identical to that of underlying SiC 1 is formed. That is, the intermediate layer disappears and thus the layer growth results in mere SiC homoepitaxial growth of an identical polarity.

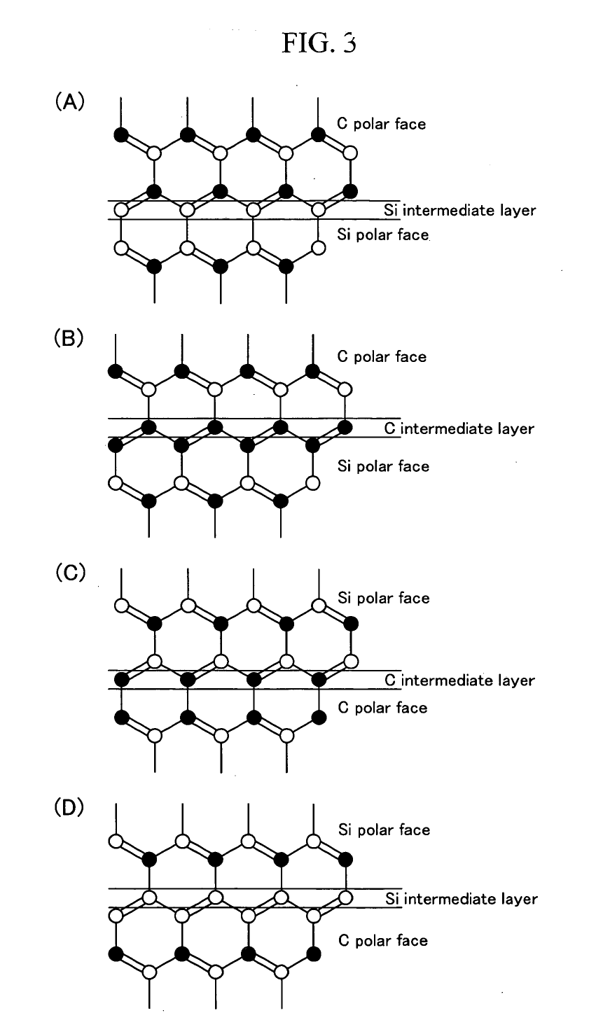

For the thickness of the intermediate layer 1b, it is possible to use an odd number of layers equal to or greater than one, as is shown by a crystal structure. However, if an Si layer thicker than necessary is introduced, a defect attributable to the lattice mismatch occurs due to a large lattice mismatch between Si and SiC. Thus, the crystallinity of an SiC polarity-reversed layer grown on the Si layer degrades. In addition, Si does not grow in a layer-shaped manner but grows in an island-shaped manner, depending on growth conditions. Consequently there arises the problem that it is not possible to control the number of layers of Si for the substrate as a whole (the intermediate layer 1b becomes thicker in island-shaped portions than in other portions). Accordingly, the intermediate layer 1b is preferably made as thin as possible, and is preferably made of one or three layers, or five layers or so. According to a semiconductor manufacturing method in accordance with the present embodiment, it is also possible to precisely deposit an SiC layer (polarity-reversed layer) having a C polarity on an SiC layer having an Si polarity through C—C bonds formed by an odd number of C intermediate layers (one layer is shown here by way of example), as illustrated in FIG. 3(B), in addition to the structure of FIG. 3(A) described heretofore. As illustrated in FIGS. 3(C) and 3(D), it is also possible to form SiC having an Si polarity on SiC having a C polarity through an odd number of C intermediate layers, or form SiC having an Si polarity on SiC having a C polarity through an odd number of Si intermediate layers. It is difficult, however, to form a C intermediate layer (corresponds to diamond) having four-coordinate C—C bonds in the deposition of C on SiC. The C intermediate layer tends to take the form of a three-coordinate graphite structure. If a graphite layer is formed, polarity reversal is no longer possible. It is therefore preferable to use Si for the intermediate layer.

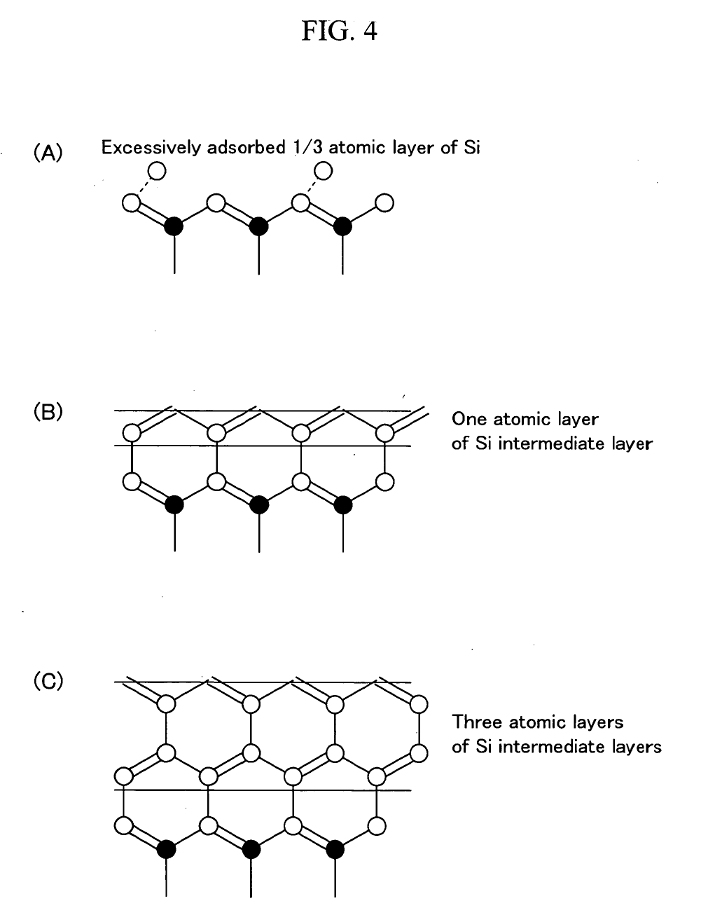

In the present embodiment, although an explanation has been made of an example in which crystal growth is initiated from a perfect Si-terminated face, it is also possible to initiate crystal growth from a state in which Si is partially adsorbed to the Si-terminated face. In an MBE method, a method for removing impurities, such as oxides, by performing high-temperature heating while applying Si irradiation is used for the cleaning of the Si polar face of SiC. A cleaned SiC surface available by this method is in a state in which a ⅓ atomic layer of Si is excessively adsorbed to an Si-terminated face, as illustrated in FIG. 4(A). In this case, supplying a ⅔ atomic layer of Si to this surface enables one atomic layer of Si to be formed as illustrated in FIG. 4(B). Likewise, supplying 2 and ⅔ atomic layers of Si enables three atomic layers of Si to be formed as illustrated in FIG. 4(C).

An important point in the above-described polarity reversal technique using an intermediate layer composed of an odd number of atomic layers is that atoms of the intermediate layers take the form of a four-coordinate structure. For example, if a C intermediate layer is used and if the layer takes the form of a three-coordinate structure, i.e., a graphite structure, it is difficult to grow satisfactory SiC, group III nitride or group II oxide on the intermediate layer, not to mention polarity reversal.

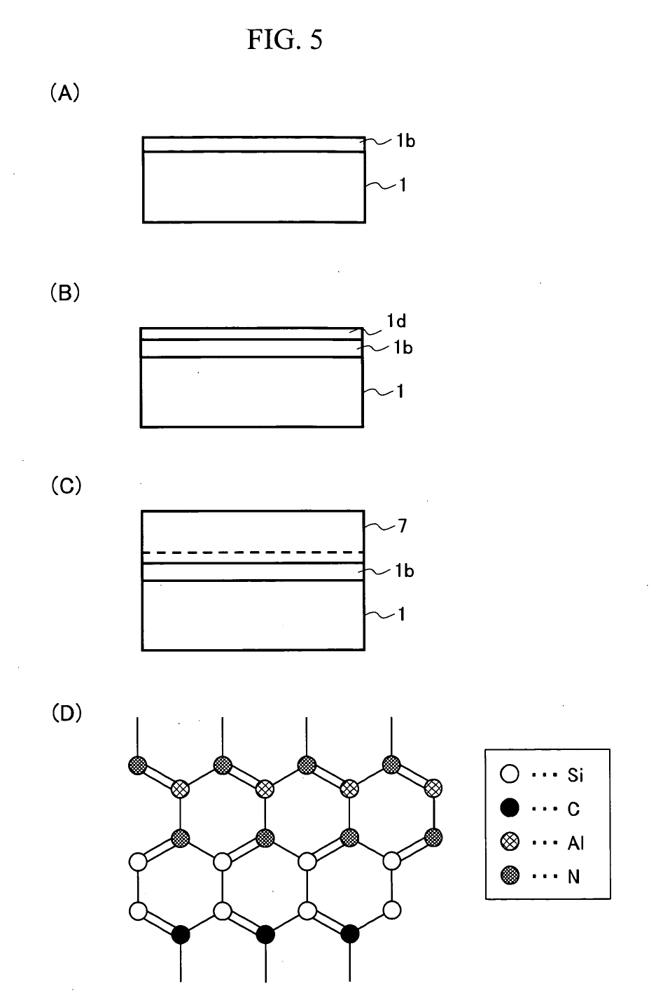

Next, a semiconductor growth method in accordance with a first modified example of the above-described first embodiment will be described while referring to FIG. 5. The semiconductor growth method in accordance with the present modified example is the same in process, up to the step of depositing the SiC intermediate layer 1b, as the SiC semiconductor growth method in accordance with the first embodiment. Unlike the first embodiment, however, SiC is not grown in the structure of FIG. 5(A) in which the intermediate layer 1b is grown. Alternatively, the semiconductor growth method of the first modified example is characterized by including the steps of:

supplying N (or O) to a substrate;

forming one atomic layer 1d of nitrogen (or oxygen);

subsequently supplying N and a group III element (or O and a group II element) to grow a group III nitride (or a group II oxide); and

thereby growing an AlN layer 7 (or a GaN layer, a ZnO layer, or the like) having a polarity opposite to that of SiC 1, as illustrated in FIG. 5(C). Note that FIG. 5 illustrates an example in which the AlN layer 7 is grown. If the intermediate layer 1b is not used, a group III nitride having a group III polarity (group II oxide having a group II polarity) generally grows on the surface of the SiC 1 of Si polarity. By taking advantage of a difference in the way Si bonding hands project after the intermediate layer 1b in accordance with the first embodiment is formed (the bonding hands project perpendicularly on an Si polar face, whereas Si bonding hands of an intermediate layer on an Si polar face project obliquely), it is possible to grow a group III nitride having a reversed polarity, i.e., an N polarity (a group

II oxide having an O polarity), as illustrated in FIG. 5(D). Like the polarity-reversed growth of SiC, polarity-reversed growth on a C polar face, i.e., the growth of a group III polar face (group II polar face) is also possible. In addition, the first modified example and the first embodiment are also in common with each other in that a four-coordinate structure is required of the intermediate layer 1b.

Next, an explanation will be made of a semiconductor device and a manufacturing method thereof in accordance with a second embodiment of the present invention. In the first embodiment, polarity reversal is achieved using the intermediate layer 1b composed of an odd number of atomic layers (formed as thin as possible and composed preferably of 1 or 3 layers, or so). Alternatively, the manufacturing method of the second embodiment is characterized by including the steps of:

intentionally growing the Si of an intermediate layer thick, in order to eliminate the effects of a polarity held by SiC;

simulatively placing a surface of the intermediate layer in a state of being equivalent to an Si(111) face having no polarities; and

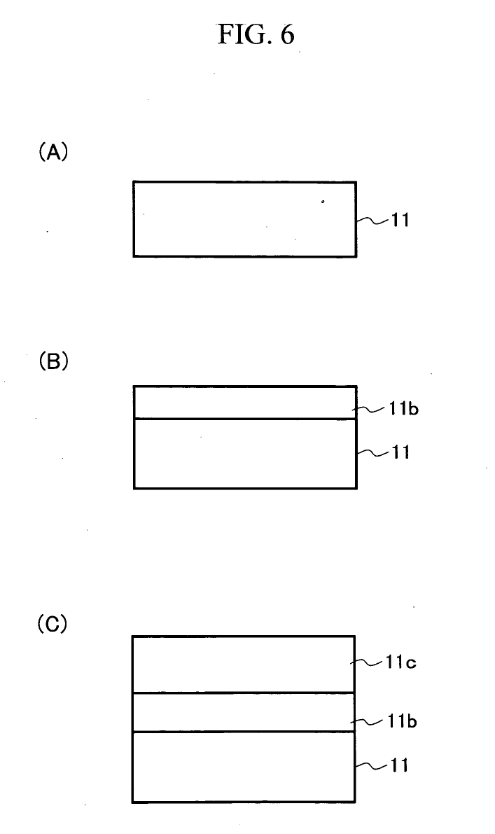

growing a layer having an opposite polarity by adjusting the growth conditions of SiC to be grown on this surface. FIGS. 6(A) to 6(C) are diagrams illustrating a method for growing an SiC semiconductor crystal in accordance with the present embodiment.

First, an SiC substrate 11 having a (0001) Si polar face is prepared, and a surface treatment for the substrate to have a clean surface is performed. Next, Si is supplied onto this substrate 11 and a Si intermediate layer 1b having a thickness of, for example, 20 nm is heteroepitaxially grown, as illustrated in FIG. 6(B). On an Si polar face of SiC, there grows a (111) face of Si (the Si(111) face has no polarities). Subsequently, SiC is grown on this Si intermediate layer 11b. SiC, whether comprised of a Si polar face or a C polar face, can be grown on the Si (111) face having no polarities. Accordingly, it is possible to perform control, as to which type of SiC to grow, by a treatment method of the Si(111) face, carbonization process conditions, growth conditions of SiC itself, and the like, set immediately before the growth of SiC. For example, if a treatment, a carbonization process, and growth conditions for the C polar face of SiC to grow are adopted, an SiC layer 11c having a C polar face grows on this Si intermediate layer 11b. Thus, the objective of polarity reversal is attained.

In this case, unlike the first embodiment, there is no need to strictly control the number of layers of Si. Accordingly, the manufacturing method of the second embodiment has the advantage of being able to reduce constraints on the formation process of the intermediate layer 11b and significantly simplify steps. However, since SiC of either polarity can grow on the Si(111) face having no polarities, there is the possibility that some amount of SiC having a polarity opposite to an intended polarity mixes with SiC having the intended polarity. In addition, since a thick layer of Si having a greatly-differing lattice constant is introduced, it is increasingly difficult to upgrade the quality of the SiC layer 11c having an opposite polarity as much as in the first embodiment that uses an extremely thin intermediate layer. Since the process is simple, however, the manufacturing method is extremely effective for application to devices in which requirements for the quality of layers having an opposite polarity are not severe, for example, to nonlinear optical elements or the like, in that this thick Si layer can be utilized for the intermediate layer. The lower limit of the thickness of the intermediate layer 11b depends on how thick the intermediate layer 11b should be, to be able to remain after the growth of SiC thereon. That is, a process of Si carbonization (conversion into SiC) is generally used before the growth of SiC on Si. If the Si intermediate layer 11b is too thin, all intermediate layers are carbonized. Carbonized regions reach the SiC substrate 11 and the carbonized layers inherit the polarity of the SiC substrate 11. Thus, SiC growth results in mere homoepitaxial growth in which a polarity is not reversed.

On the other hand, the upper limit of the thickness of the intermediate layer depends on the resolution of lithography used in subsequent device fabrication. That is, if the Si intermediate layer 11b is too thick, deeper etching becomes necessary in order to remove partial regions of the Si intermediate layer 11b. Consequently, there are the problems of aspect ratio constraints in etching treatment and a degradation in the accuracy of minimum processing dimensions within the face concerned. For example, assuming a minimum processing dimension of 0.5 μm, then the thickness of the Si intermediate layer 11b is desirably 0.1 μm or smaller, i.e., 100 nm or smaller. Note that if a thick intermediate layer is used, the composition thereof can be an arbitrary composition containing one of Si, C, and Ge. As far as polarity reversal by the thick intermediate layer described here is concerned, the intermediate layer need not necessarily take the form of a four-coordinate structure. In order to maintain the crystallinity of a polarity-reversed layer to be satisfactory, however, it is desirable to allow the intermediate layer to have orientation of at least some sort. More desirably, the intermediate layer is epitaxially grown with respect to SiC. Even more desirably, the intermediate layer is epitaxially grown into one of a diamond structure, a zinc blende structure and a wurtzite structure. From the above-described point of view, it can be said that an epitaxially-grown layer of Si or Si1-xGex having a diamond structure is best suited as the intermediate layer.

Next, an explanation will be made of a semiconductor growth method in accordance with a first modified example of the second embodiment. The semiconductor growth method in accordance with the present modified example is the same in process, up to the step of depositing the intermediate layer 11b, as the SiC semiconductor growth method in accordance with the second embodiment. Unlike the second embodiment, however, SiC is not grown but a group III nitride (or a group II oxide) is grown after the growth of the intermediate layer (FIG. 6(B)). On Si(111) face, there can be grown a group III nitride (group II oxide) having either a group III polar face (group II polar face) or an N polar face (O polar face) by selecting growth conditions. Here, since an SiC substrate has an Si polarity, a surface of the Si intermediate layer is treated, initial growth conditions are selected, and growth is performed, so that the group III nitride grows with an N polarity(O polarity) corresponding to an opposite polarity. Then, the group III nitride (group II oxide) having an N polarity (O polarity) is obtained on this Si intermediate layer. Thus, the objective of polarity reversal is attained. Like the polarity reversal of SiC, polarity-reversed growth on a C polar face, i.e., the growth of a group III polar face (group II polar face) is also possible. In addition, requirements for the intermediate layer (epitaxial growth with respect to the SiC substrate) are the same as those in the second embodiment.

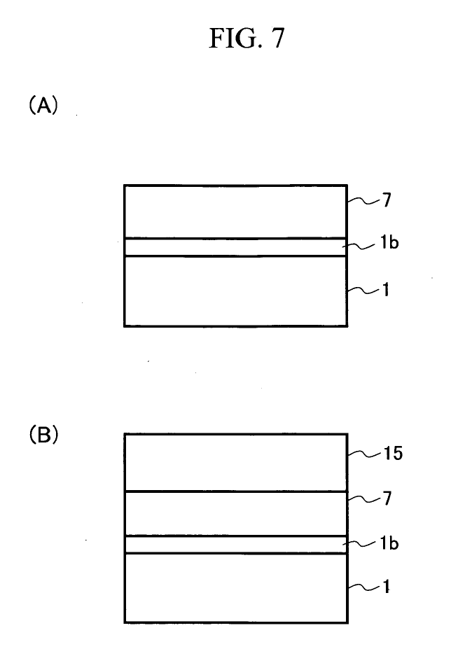

Next, a semiconductor growth method in accordance with modified examples of the first and second embodiments will be described, while referring to FIG. 7. In the semiconductor growth method in accordance with the present modified examples, a group III nitride or group II oxide 15 is grown on SiC 1 using a usual method, after the completion of growth according to the first or second embodiment, i.e., after an SiC layer 7 having an opposite polarity is formed using the intermediate layer 1b, as illustrated in FIG. 7(A). The group III nitride or group II oxide 15 grows while inheriting the polarity of SiC in a surface of the nitride during growth. As a result, as illustrated in FIG. 7(B), it is possible to grow the group III nitride 15 opposite in polarity to the SiC substrate 1.

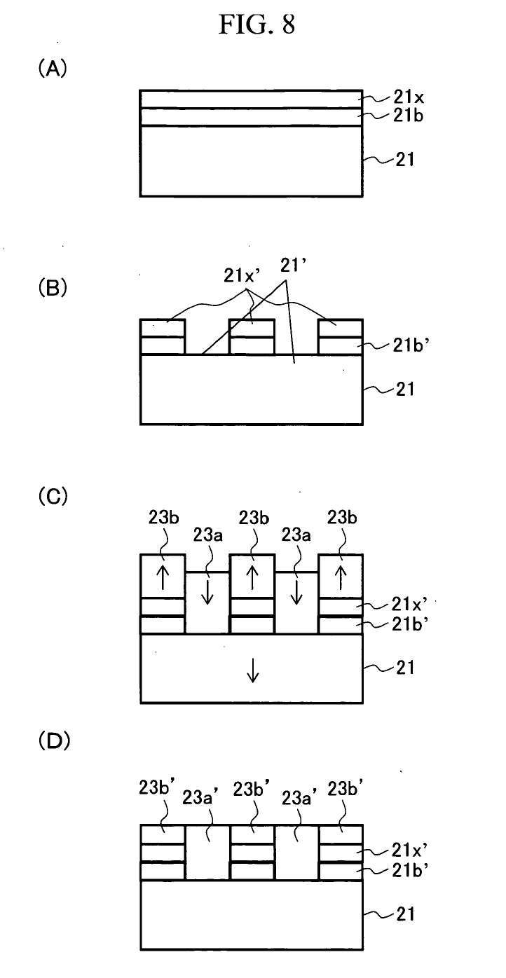

Next, an explanation will be made of a semiconductor device and a manufacturing method thereof in accordance with a third embodiment of the present invention. FIG. 8 is a simplified process diagram illustrating the method for manufacturing the semiconductor device in accordance with the present embodiment. As illustrated in FIG. 8(A), an intermediate layer 21b is first formed on an SiC substrate 21 having an Si polar face in the same way as in the first or second embodiment, and then SiC 21x having a C polar face is grown. Subsequently, as illustrated in FIG. 8(B), SiC 21x having a C polar face is processed using, for example, a lithography method, thereby forming a structure having a region 21x′ in which the SiC 21x is left and a region 21′ in which the SiC 21x and the intermediate layer 21b are removed to expose a surface of SiC 21. For the removal of the SiC 21x and the intermediate layer 21b, such a technique as reactive ion etching is used specifically. In the removal, it is desirable to remove only the SiC 21x and the intermediate layer 21b. No problems are caused, however, even if a surface of the SiC substrate 21 is more or less removed after the surface is exposed, since the surface is buried in subsequent steps. If Si and C are supplied to the entire surface of the structure illustrated in FIG. 8(B) to deposit SiC, then an SiC layer 23b having a reversed polarity, i.e., a C polar face is deposited on the region 21x′ in which the SiC 21x is left. In contrast, an SiC layer 23a having the same Si polar face as that of the SiC substrate 21 is deposited on the region in which the SiC 21x and the intermediate layer 21b are removed. That is, as illustrated in FIG. 8(C), the SiC layer 23a and the SiC layer 23b having mutually different polarities can also be formed, so as to be arranged, for example, both in a striped manner and in an alternate manner in one direction within a plane. Note that polarities in FIG. 8 are schematically represented by arrows. As described above, according to the semiconductor device and the manufacturing method thereof in accordance with the present embodiment, it is possible to realize arbitrary structures, including a structure in which types of SiC having different polar faces are periodically formed. Note that an irregularity occurs on a surface of the structure, as illustrated in FIG. 8(C), due to steps already present at a point in time of FIG. 8(B), a difference in growth rate dependent on a polarity, or the like. If necessary, it is possible to remove the irregularity using a surface polishing method (CMP method or the like) or the like, thereby obtaining a structure in which the outermost surface thereof is planarized, as illustrated in FIG. 8(D).

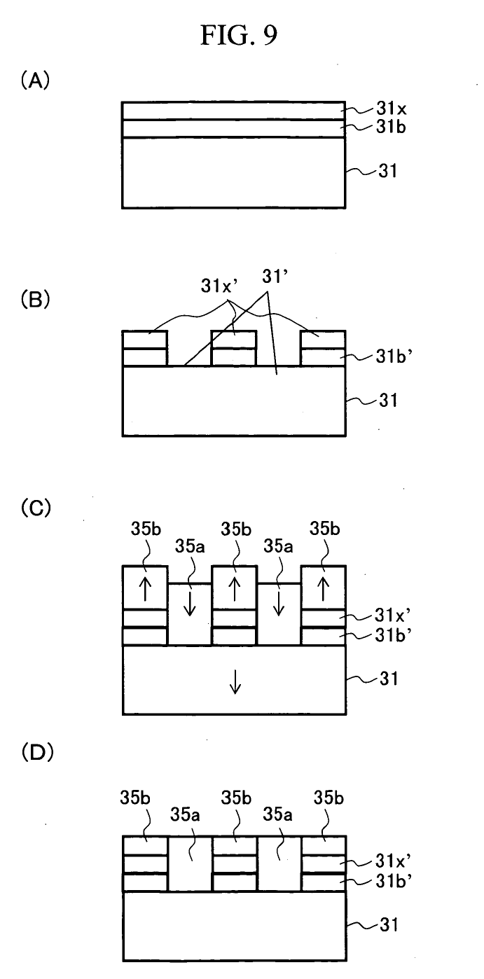

Next, an explanation will be made of a semiconductor device and a manufacturing method thereof in accordance with a fourth embodiment of the present invention. FIG. 9 is a simplified process diagram illustrating the method for manufacturing the semiconductor device in accordance with the present embodiment. As illustrated in FIG. 9(A), an intermediate layer 31b is first formed on an SiC substrate 31 having an Si polar face in the same way as in the first or second embodiment, and then SiC 31x having a C polar face is grown. Subsequently, as illustrated in FIG. 9(B), the SiC 31x having a C polar face and the intermediate layer 31b are processed using, for example, a lithography method, to form a region 31x′ in which the SiC 31x is left and a region 31′ in which the SiC 31x and the intermediate layer 31b are removed. If, under the condition in which the structure illustrated in FIG. 9(B) is formed, Al and N are supplied to the entire surface of the structure to deposit AlN, then an AlN layer 35b having a reversed polarity, i.e., an N polar face is formed on the region 31x′ in which the SiC 31x is left. In contrast, an AlN layer 35a having a group III polar face (Al polar face in this case) appropriate for the Si polarity of the SiC substrate 31 is deposited on the region in which the SiC 31x and the intermediate layer 31b are removed. That is, as illustrated in FIG. 9(C), the AlN layers 35a and 35b having mutually different polarities can be formed, so as to be arranged, for example, both in a striped manner and in an alternate manner in one direction within a plane (in the figure, polarities are schematically represented by arrows).

As described above, according to the semiconductor device and the manufacturing method thereof in accordance with the present embodiment, it is possible to realize arbitrary structures, including a structure in which AlN layers having different polar faces are periodically formed in one direction within a plane of the substrate. Note that an irregularity occurs on a surface of the structure, as illustrated in FIG. 9(C), due to steps already present at a point in time of FIG. 9(B) or a difference in growth rate dependent on a polarity. If necessary, it is possible to remove such an irregularity using a polishing method or the like. Thus, the outermost surface of the structure can be planarized, as illustrated in FIG. 9(D). A thin film to be grown is not limited to an AlN layer. Alternatively, the thin film can be one of arbitrary group III nitrides, group II oxides and multilayer films thereof, including an AlxGal-xN layer, a GaN layer and a ZnO layer. An advantage of this method is that the polarity of a group HI nitride or a group II oxide is defined by a polarity of SiC developed on a surface thereof. Accordingly, no particular constraints are placed on the growth conditions of nitrides and oxides. Alternatively, there may be used usual growth conditions under which nitrides and oxides can be grown on SiC with high quality.

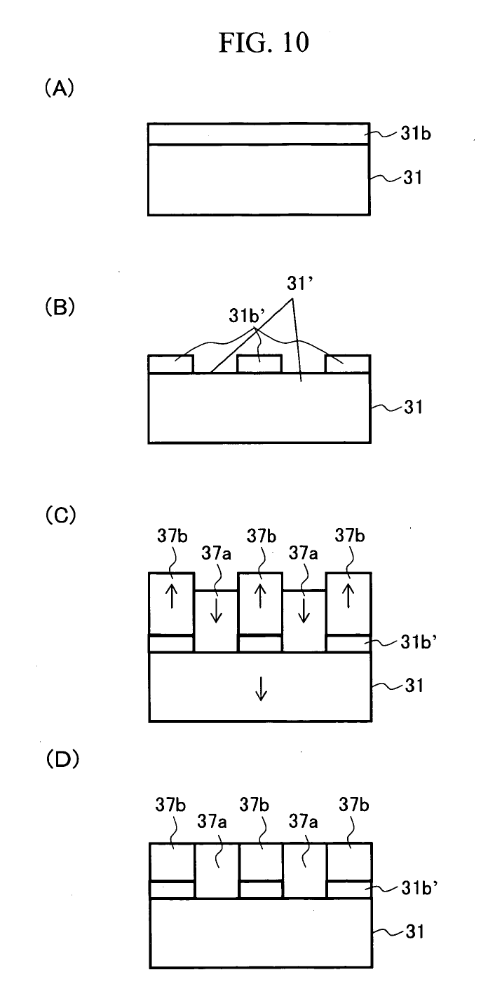

Next, an explanation will be made of a semiconductor device and a manufacturing method thereof in accordance with a fifth embodiment of the present invention. FIG. 10 is a simplified process diagram illustrating the method for manufacturing the semiconductor device in accordance with the present embodiment. As illustrated in FIG. 10(A), an intermediate layer 31b is first formed on an SiC substrate 31 having an Si polar face in the same way as in the first or second embodiment. Subsequently, as illustrated in FIG. 10(B), the intermediate layer 31b is processed using, for example, a lithography method, to form a region 31b′ in which the intermediate layer 31b is left and a region 31′ in which the intermediate layer 31b is removed. For the removal, chemical etching or the like is used specifically. In the removal, it is desirable to remove only the intermediate layer 31b. No problems are caused, however, even if a surface of the SiC substrate 31 is more or less removed, since the surface is buried in subsequent steps. If AlN is deposited on the entire surface of this structure under the condition that the AlN has an N polarity on the intermediate layer 31b, then an AlN layer 37b having a reversed polarity, i.e., an N polar face, is deposited on the region 31b′ in which the intermediate layer 31b is left. In contrast, an AlN layer 37a, in which the polarity of AlN depends on the polarity of SiC, i.e., which has an Al polar face appropriate for the Si polar face of the SiC substrate 1, is deposited on the region in which the intermediate layer 31b is removed. That is, as illustrated in FIG. 10(C), the AlN layer 37a and the AlN layer 37b having mutually different polarities can be formed, so as to be arranged, for example, both in a striped manner and in an alternate manner in one direction within a plane (in the figure, polarities are schematically represented by arrows). As described above, according to the semiconductor device and the manufacturing method thereof in accordance with the present embodiment, it is possible to realize arbitrary structures, including a structure in which AlN layers having different polar faces are periodically formed. Note that an irregularity occurs on a surface of the structure, as illustrated in FIG. 10(C), due to steps already present at a point in time of FIG. 10(B) or a difference in growth rate dependent on a polarity. If necessary, it is possible to remove this irregularity using a polishing method or the like. Thus, the outermost surface of the structure can be planarized, as illustrated in FIG. 10(D). Note that a thin film to be grown is not limited to an AlN thin film. Alternatively, the thin film can be one of arbitrary group III nitrides, group II oxides and multilayer films thereof. One advantage of this method is that the intermediate layer 31b is made of Si or Sil-xGex and, therefore, can be removed by chemical etching more easily, compared with SiC. Another advantage is that since the intermediate layer 31b is extremely thin, it is possible to reduce the irregularity of a surface in FIG. 9(C). Thus, in most cases, it is possible to skip a step of planarization by polishing. On the other hand, it is necessary to select the growth conditions of AlN or the like, so that polarities are opposite to each other on the intermediate layer 31b′ and on the SiC 31′. Such conditions as described above in general differ greatly from the growth conditions of a high-quality crystal. Accordingly, there is the need for contrivance for improving crystallinity by switching to the growth conditions of high-quality crystals after growth to a certain thickness.

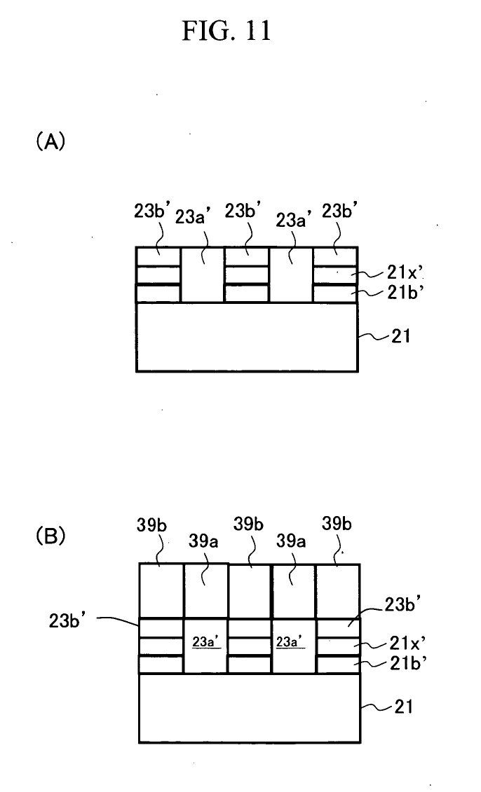

It is also possible to fabricate a polarization reversal structure of a group III nitride or a group II oxide, as illustrated in FIG. 11(B), in addition to those of the fourth and fifth embodiments, by growing an arbitrary group III nitride or group II oxide, such as AlN, in the SiC polarization reversal structure (FIG. 11(A)) fabricated in the third embodiment. FIG. 11(A) is a drawing corresponding to FIG. 8(D), wherein group III nitride (for example, AlN) layers 23a′ having an Al polar face and group III nitride (for example, AlN) layers 23b′ having an N polar face are arranged alternately on the outermost surface of SiC 21. A group II oxide may be used in place of the group III nitride. It is also possible that in FIG. 11(B), a polarization reversal structure of group III nitrides 39a and 39b or group II oxides, like the structure of FIG. 11(A), is fabricated on SiC 23a′ and 23b′.

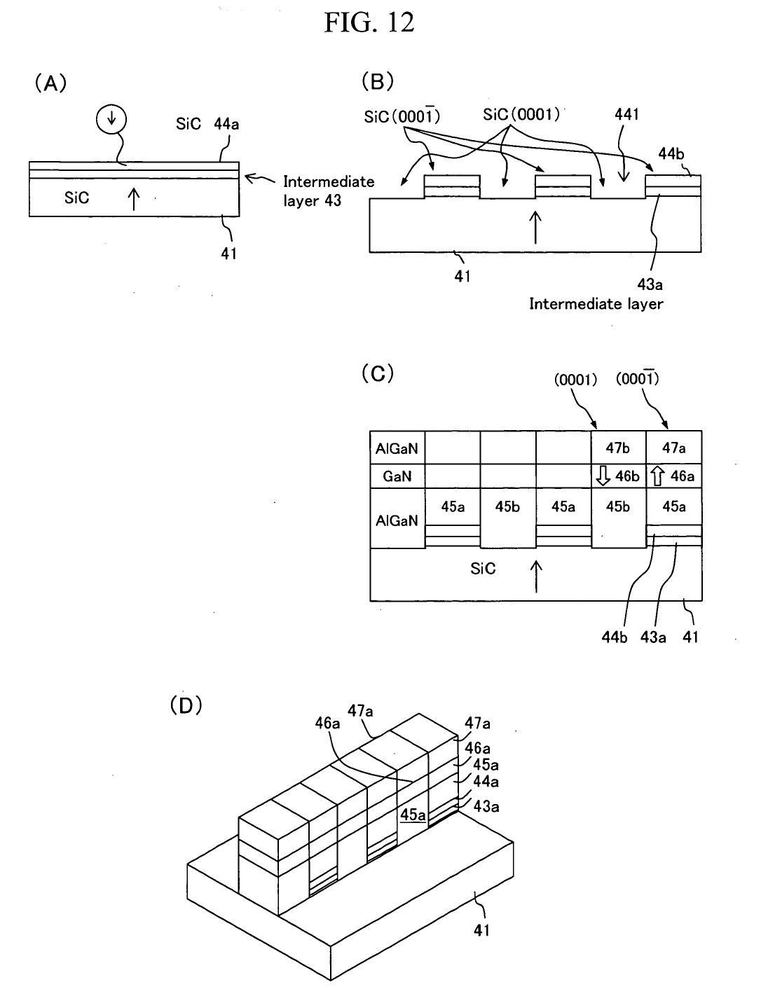

Next, an explanation will be made of a semiconductor device having a waveform conversion function fabricated by applying the above-described fourth embodiment, as a technology in accordance with the sixth embodiment of the present invention. FIGS. 12(A) to 12(D) illustrate examples of steps of fabricating a quasi-phase matched wavelength conversion element having a periodically space-reversed structure.

As illustrated in FIG. 12(A), a 10 nm-thick Si intermediate layer 43 is first formed on an SiC substrate 41 using an MBE method. Next, a 40 nm-thick SiC polarity-reversed layer 44a is formed using the same MBE apparatus. Subsequently, as illustrated in FIG. 12(B), the SiC polarity-reversed layer 44a and the intermediate layer 43 are removed in a striped manner, at line-and-space intervals of 500 nm/500 nm, using a photolithography method and reactive ion etching, thereby exposing the SiC face having an Si polarity on a surface.

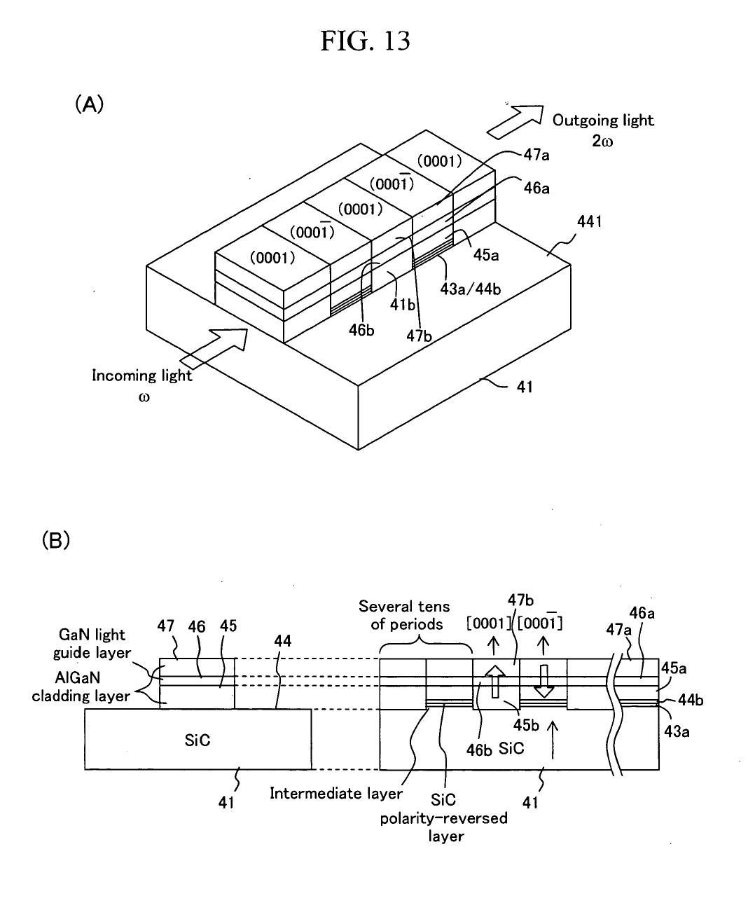

Next, as illustrated in FIG. 12(C), AlGaN is grown on a surface using an MBE method, a VPE method, or the like. Then, the device being fabricated is temporarily taken out of the apparatus, and the surface is planarized by chemical-mechanical polishing and cleaned using a chemical. The device is once again introduced into the growth apparatus and an AlGaN/GaN/AlGaN optical waveguide structure is grown therein. At this time, nitride layers 45b/46b/47b having a group III polarity grow in an opening region having an Si polarity, whereas group III nitride layers 45a/46a/47a having an N polarity grow on an SiC polarity-reversed layer 44b having a C polarity. Consequently, as illustrated in the cross-sectional view of FIG. 12(C) and in the perspective view of FIG. 12(D), it is possible to form, on the SiC substrate 41, a periodic structure in which GaN layers 46b and GaN polarity-reversed layers 46a, each of which is sandwiched by AlGaN layers, are periodically arranged in a striped manner. In the periodic structure formed on a surface 441 of the SiC substrate 41, if light (ω) is introduced from a lateral edge face toward the direction in which the layers are periodically arranged, as illustrated in FIGS. 13(A) and 13(B), there are caused the nonlinear optical effect of GaN and a quasi-phase matching effect due to periodic polarization reversal. A high-efficiency second harmonic generation device (2ω) can thus be realized. The GaN layer (light guide layer) and the AlGaN layer (cladding layer) in FIG. 12 can be replaced with another group III nitride layer, such as AlxGayInl-x-yN, or a multilayer structure thereof, as necessary. Although an element based on a group III nitride has been shown here, it is also possible to fabricate an element based on a group II oxide. In addition, it is needless to say that the line-and-space interval of a stripe is correctly set from the wavelength dispersion of a refractive index, so that quasi-phase matching is achieved.

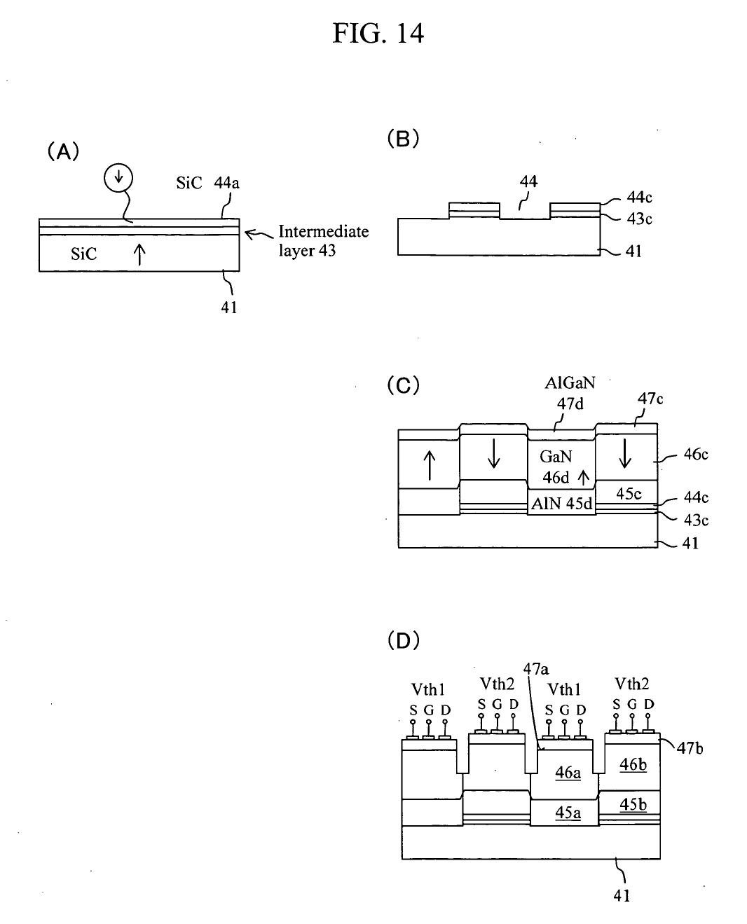

Next, a semiconductor device fabricated by applying the fourth embodiment will be described as a seventh embodiment of the present invention, while referring to drawings. FIGS. 14(A) to 14(D) are diagrams illustrating a procedure for fabricating a GaN-based high electron mobility transistor(HEMT) integrated circuit in accordance with the present embodiment. As illustrated in FIG. 14(A), an SiC polarity-reversed layer 44a is formed on an SiC substrate 41 having an Si polar face using the same procedure as in the above-described sixth embodiment. Next, on the basis of an integrated circuit layout, an SiC polarity-reversed layer 44a and an intermediate layer 43 are removed in a region in which a HEMT, which is desired to have a small threshold voltage, is desired to be located, as illustrated in FIG. 14(B). After treatments, such as gas etching and chemical cleaning, are performed on the resultant surface as necessary, using an MBE method, a VPE method or the like, an AlN layer 45, a GaN layer 46, and an AlGaN layer 47 are formed, so as to be formed into a HEMT structure. This structure works as an AlGaN/GaN heterojunction HEMT. In the above-described nonlinear optical device, it is extremely important to interconnect a polarity-unreversed region (layer denoted by an up-arrow followed by an up-arrow) and a polarity-reversed region (layer denoted by a down-arrow followed by an up-arrow), in order to make the device function as an optical waveguide. Accordingly, there has been the need to perform chemical-mechanical polishing as necessary, in order to make the surfaces of both regions level with each other. In the case of a HEMT integrated circuit, however, each region independently functions as a transistor. Consequently, if any problems are not caused in an interconnection step, a step of aligning the heights of the regions by polishing may be skipped.

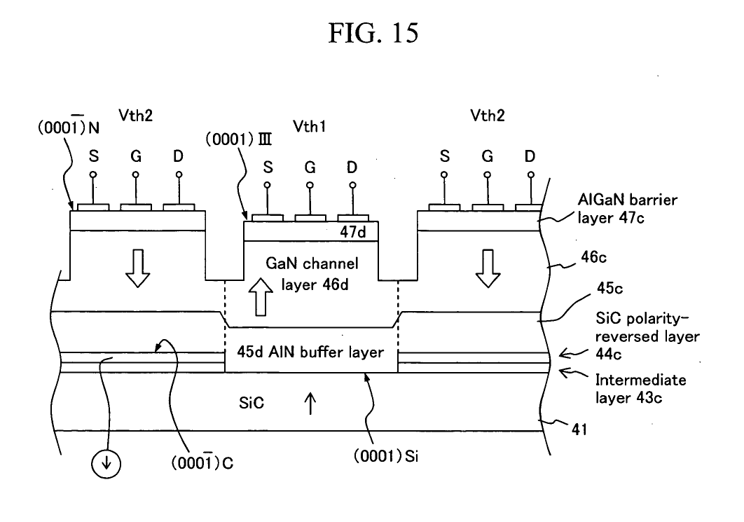

As illustrated in FIGS. 14(D) and 15, the HEMT having a group III polar face and formed on an Si polar face is caused to have a small threshold voltage Vth1 (large negative value, showing a normally-on characteristic) by the polarizing effect of a group III nitride. In the case of the HEMT having an N polar face and formed on an SiC polarity-reversed layer, i.e., on a C polar face, however, a two-dimensional electron gas is less likely to be formed due to the polarizing effect. Thus, the HEMT is caused to have a large threshold voltage Vth2 (near 0 V or a positive value, showing a normally-off characteristic or close thereto). As described above, it is possible to simultaneously fabricate HEMTs having threshold voltages Vth greatly different from each other on the same substrate. Use of a technique in accordance with the present embodiment has the advantage of being able to increase the freedom of a manufacturing process and circuit design.

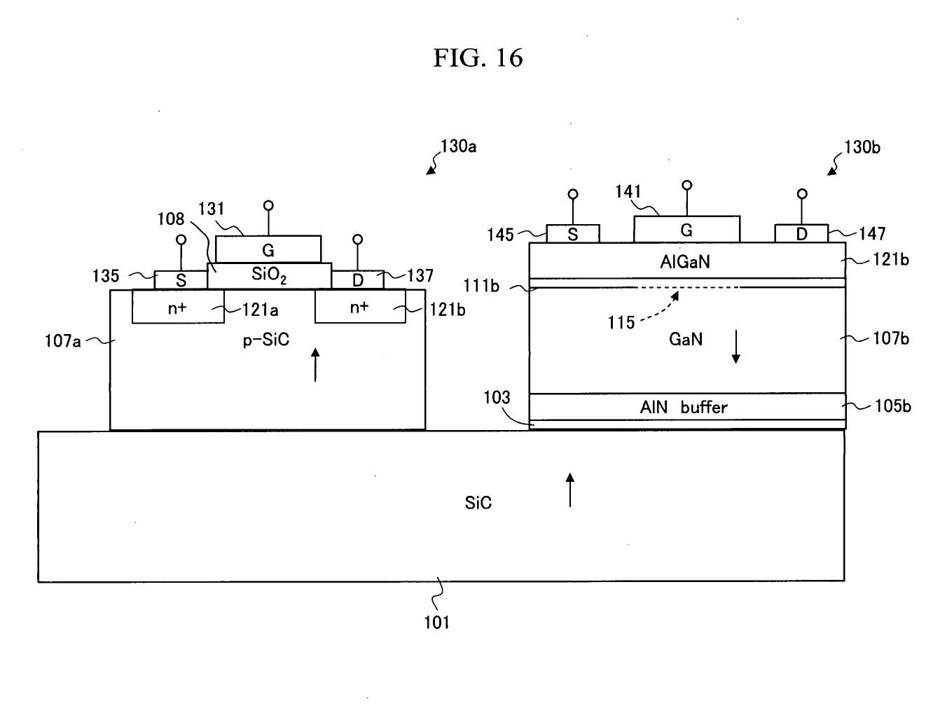

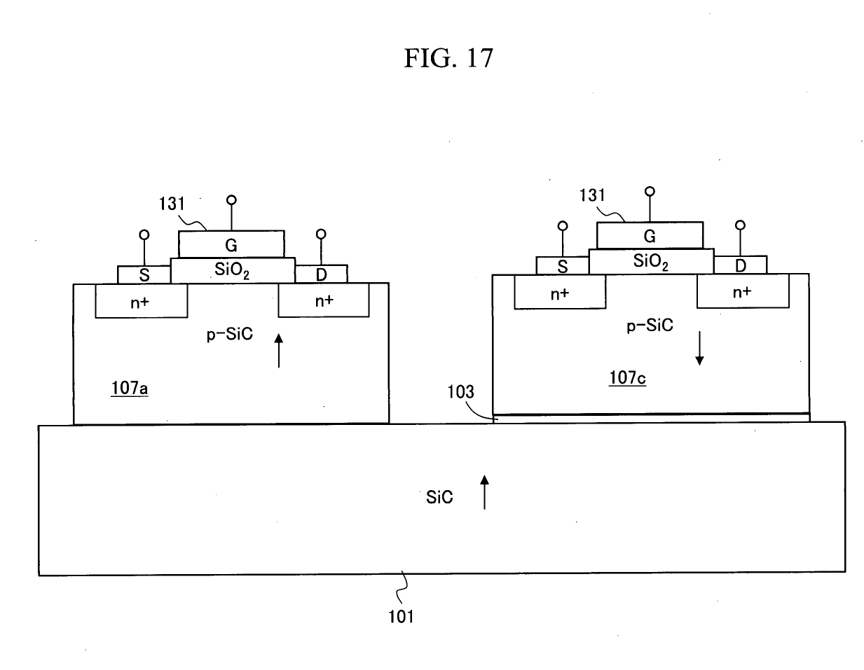

Next, as modified examples of the seventh embodiment of the present invention, it is possible to fabricate: such a device as described above and illustrated in FIG. 15 in which group III nitride devices (HEMTs) are located in both a polarity-unreversed region and a polarity-reversed region; such a device as illustrated in FIG. 16 in which an SiC device (nMOSFET) is located in a polarity-unreversed region and a group III nitride device (HEMT) is located in a polarity-reversed region; and such a device as illustrated in FIG. 17 in which an SiC device (nMOSFET) is located in both a polarity-unreversed region and a polarity-reversed region.

The device of FIG. 16 includes an SiC substrate 101, and a first multilayer structure 130a and a second multilayer structure 130b formed on the substrate. The second multilayer structure 130b is a structure which is formed through an intermediate layer 103 and the polarity of which is reversed against that of the SiC substrate 101. In the structure, an AlN buffer layer 105b, a GaN layer 107b, and an AlGaN electron donation layer 121b are grown in this order. On the other hand, a p-SiC layer 107a having the same polarity as that of the SiC substrate 101 is formed in the first multilayer structure 130a. In the first multilayer structure 130a, a gate electrode G131 is formed through a gate insulating film 108 made of SiO₂, high-concentration n-type impurity regions (a source) 121a and a drain 121b are formed on one and the other sides of the gate insulating film 108, respectively, and in the vicinity of a surface of p-SiC 107a. In addition, source and drain electrodes 135 and 137 are formed for the respective regions, thereby constituting an n-channel SiC MOSFET. In the first multilayer structure 130a, there is formed a HEMT structure having a channel layer which is a two-dimensional electron gas layer 111b and is modulated by a gate electrode 141, as described above, wherein source and drain electrodes 145 and 147 are formed for the respective regions. Arrows denote polarities. According to such a structure as described above, it is possible to form an SiC-based high-withstand voltage MOSFET and a high-frequency HEMT utilizing a GaN/AlGaN heterojunction on the same SiC substrate.

In FIG. 17, an SiC MOSFET including SiC the polarity of which has been reversed through an intermediate layer 103 is formed in place of the HEMT illustrated in FIG. 16, along with the SiC MOSFET illustrated in FIG. 16. The characteristics of an SiC MOSFET, such a threshold value, greatly vary depending on a polar face with which the MOSFET is fabricated. By fabricating the device as described above, it is possible to integrate SiC MOSFETs having different threshold voltages on the same SiC substrate.

As a matter of course, it is also possible to fabricate a device in which the group III nitride is replaced with a group II oxide. In addition, the elements are not limited to a MOSFET and a HEMT but can be arbitrary elements, such as diodes, light-emitting diodes, laser diodes, or bipolar transistors. Since SiC, a group III nitride and a group II oxide have strong polarities and the optimum polarity differs depending on the type of device, a technique to integrate elements of both polarities on a single substrate is extremely useful, as described in the present embodiment. For the fabrication of a polarity-reversed region, it is possible to freely combine the first to fifth embodiments and the modified examples thereof. An SiC device is generally fabricated on a face inclined two to nine degrees from a (0001) face or a (000-1) face. Accordingly, it is possible to utilize a face of 4H-SiC inclined four degrees in a <11-20> direction from the (0001) face, as an SiC substrate, in the case of, for example, the device illustrated in FIG. 17. Note here that since the intermediate layer is deposited so as to have an epitaxial relationship with the substrate, the polarity-reversed layer on the intermediate layer has a face inclined four degrees in the <11-20> direction from the (000-1) face.

A semiconductor technology in accordance with the present invention is also applicable to, for example, the fabrication of an optical device based on a group III nitride or a group II oxide, an optical integrated circuit in which SiC electronic devices are integrated, a group III nitride, a group II oxide, and an SiC micromachine (MEMS), in addition to a nonlinear optical device and an integrated circuit. Furthermore, using the same technique, it is also possible to fabricate a structure in which polarity-reversed and polarity-unreversed regions coexist, not only for group III nitrides and group II oxides but also for arbitrary semiconductors and dielectric materials capable of growth while inheriting the polarity of SiC.

### INDUSTRIAL APPLICABILITY

According to the present invention, it is possible to fabricate an SiC-based polarity-reversed layer with ease and precision. The present invention is applicable to a variety of fields, including, in particular, a quasi-phase matched nonlinear optical device and a HEMT integrated circuit.

1. A semiconductor device comprising:
a first SiC layer having a first polar face;
an intermediate layer formed by being deposited on the first SiC layer and comprised of an Si layer or a C layer; and
a second SiC layer formed by being deposited on the intermediate layer and having a second polar face opposite to the first polar face.

2. A semiconductor device comprising:
a first SiC layer having a first polar face;
an intermediate layer formed by being deposited on the first SiC layer and comprised of an Si layer or a C layer; and
a first group III nitride layer or group II oxide layer formed by being deposited on the intermediate layer and having a second polar face opposite to the first polar face.

3. A semiconductor device comprising:
a first SiC layer having a first polar face;
an intermediate layer formed by being deposited on the first SiC layer and comprised of an Si layer or a C layer;
a second SiC layer formed by being deposited on the intermediate layer and having a second polar face opposite to the first polar face; and
a first group III nitride layer or group II oxide layer deposited on the second SiC layer and having a polar face identical to the second polar face.

4. The semiconductor device according to claim 1, wherein there is a region on the first SiC layer in which the intermediate layer does not exist, and a third SiC layer having a polar face identical to the first polar face is formed in the region.

5. The semiconductor device according to claim 1, wherein there is a region on the first SiC layer in which the intermediate layer does not exist, and a second group III nitride layer or group II oxide layer having a polar face identical to the first polar face is formed in the region.

6. The semiconductor device according to claim 1, wherein there is a region on the first SiC layer in which the intermediate layer does not exist, a third SiC layer having a polar face identical to the first polar face is formed in the region, and a second group III nitride layer or group II oxide layer having a polar face identical to the first polar face is further formed on the third SiC layer.

7-8. (canceled)

9. The semiconductor device according to claim 1, characterized in that the intermediate layer is an odd number of atomic layers.

10. The semiconductor device according to claim 1, characterized in that the intermediate layer is one atomic layer.

11. The semiconductor device according to claim 1, characterized in that the thickness of the intermediate layer is 100 nm or smaller.

12. The semiconductor device according to claim 1, characterized in that the first polar face is the (0001) Si polar face of 4H-, 6H- or 15R-SiC or the (111) Si polar face of 3C-SiC, or a face the deviation of which in a plane direction from the (0001) Si polar face or the (111) Si polar face is no larger than 10 degrees.

13. The semiconductor device according to claim 1, characterized in that the first polar face is the (000-1) C (carbon) polar face of 4H-, 6H- or 15R-SiC or the (-1-1-1) C polar face of 3C-SiC, or a face the deviation of which in a plane direction from the (000-1) C polar face or the (-1-1-1) C polar face is no larger than 10 degrees.

14. The semiconductor device according to claim 2, characterized in that the first polar face is the (0001) Si polar face of 4H-, 6H- or 15R-SiC or the (111) Si polar face of 3C-SiC, or a face the deviation of which in a plane direction from the (0001) Si polar face or the (111) Si polar face is no larger than 10 degrees, and the second polar face is the (000-1) nitrogen or O (oxygen) polar face of a group III nitride layer or a group II oxide layer, or a face the deviation of which in a plane direction from the (000-1) face is no larger than 10 degrees.

15. The semiconductor device according to claim 2, characterized in that the first polar face is the (000-1) C polar face of 4H-, 6H- or 15R-SiC or the (-1-1-1) Si polar face of 3C-SiC, or a face the deviation of which in a plane direction from the (000-1) C polar face or the (-1-1-1) Si polar face is no larger than 10 degrees, and the second polar face is the (0001) group III or group II polar face of a group III nitride layer or a group II oxide layer, or a face the deviation of which in a plane direction from the (0001) face is no larger than 10 degrees.

16. A waveguide-type quasi-phase matched wavelength conversion element comprising:
a first optical waveguide structure formed on a first SiC layer having a first polar face and comprised of a first group III nitride or a group II oxide having a polar face identical to the first polar face; and
a second optical waveguide structure comprised of a second group III nitride or group II oxide, formed by being deposited, through an intermediate layer formed by being deposited on the first SiC layer and comprised of an Si layer or a C layer, on the intermediate layer and having a polar face opposite to the first polar face;
wherein the first optical waveguide structure and the second optical waveguide structure are spatially arranged and the optical waveguides of both the first and second optical waveguide structures are connected to each other.

17. An integrated circuit comprising:
a first semiconductor device formed on a first SiC layer having a first polar face and comprised of SiC, a group III nitride or a group II oxide having a polar face identical to the first polar face; and
a second semiconductor device comprised of SiC, a group III nitride or a group II oxide, formed by being deposited, through an intermediate layer formed by being deposited on the first SiC layer and comprised of an Si layer or a C layer, on the intermediate layer and having a polar face opposite to the first polar face.

18. A semiconductor device comprising:
a first SiC layer having a first polar face;
an intermediate layer formed by being deposited on the first SiC layer and comprised of an SiₓGe₁₋ₓ layer; and
a second SiC layer formed by being deposited on the intermediate layer and having a second polar face opposite to the first polar face.

19. The integrated circuit according to claim 17, characterized in that the first semiconductor device and the second semiconductor device are high electron mobility transistors (HEMTs) having different threshold values.

20. The integrated circuit according to claim 17, characterized in that the first semiconductor device and the second semiconductor device are SiC MOSFETs having different threshold values.

21. The integrated circuit according to claim 17, characterized in that the first semiconductor device is an SiC MOSFET and the second semiconductor device is a high electron mobility transistor (HEMT).

22. A semiconductor substrate comprising:
a first SiC layer having a first polar face;
an intermediate layer formed by being deposited on the first SiC layer and comprised of an Si layer or a C layer; and
a second SiC layer formed by being deposited on the intermediate layer and having a second polar face opposite to the first polar face.

23. A semiconductor substrate comprising:
a first SiC layer having a first polar face;
an intermediate layer formed by being deposited on the first SiC layer and comprised of an Si layer or a C layer; and
a first group III nitride layer or group II oxide layer formed by being deposited on the intermediate layer and having a second polar face opposite to the first polar face.

24. A semiconductor substrate comprising:
a first SiC layer having a first polar face;
an intermediate layer formed by being deposited on the first SiC layer and comprised of an Si layer or a C layer;
a second SiC layer formed by being deposited on the intermediate layer and having a second polar face opposite to the first polar face; and
a first group III nitride layer or group II oxide layer formed by being deposited on the second SiC layer and having a polar face identical to the second polar face.

25. The semiconductor device according to claim 2, wherein there is a region on the first SiC layer in which the intermediate layer does not exist, and a third SiC layer having a polar face identical to the first polar face is formed in the region.

26. The semiconductor device according to claim 3, wherein there is a region on the first SiC layer in which the intermediate layer does not exist, and a third SiC layer having a polar face identical to the first polar face is formed in the region.

27. The semiconductor device according to claim 2, wherein there is a region on the first SiC layer in which the intermediate layer does not exist, and a second group III nitride layer or group II oxide layer having a polar face identical to the first polar face is formed in the region.

28. The semiconductor device according to claim 3, wherein there is a region on the first SiC layer in which the intermediate layer does not exist, and a second group III nitride layer or group II oxide layer having a polar face identical to the first polar face is formed in the region.

29. The semiconductor device according to claim 2, wherein there is a region on the first SiC layer in which the intermediate layer does not exist, a third SiC layer having a polar face identical to the first polar face is formed in the region, and a second group III nitride layer or group II oxide layer having a polar face identical to the first polar face is further formed on the third SiC layer.

30. The semiconductor device according to claim 3, wherein there is a region on the first SiC layer in which the intermediate layer does not exist, a third SiC layer having a polar face identical to the first polar face is formed in the region, and a second group III nitride layer or group II oxide layer having a polar face identical to the first polar face is further formed on the third SiC layer.

31. The semiconductor device according to claim 2, characterized in that the intermediate layer is an odd number of atomic layers.

32. The semiconductor device according to claim 3, characterized in that the intermediate layer is an odd number of atomic layers.

33. The semiconductor device according to claim 2, characterized in that the intermediate layer is one atomic layer.

34. The semiconductor device according to claim 3, characterized in that the intermediate layer is one atomic layer.

35. The semiconductor device according to claim 2, characterized in that the thickness of the intermediate layer is 100 nm or smaller.

36. The semiconductor device according to claim 3, characterized in that the thickness of the intermediate layer is 100 nm or smaller.

37. The semiconductor device according to claim 2, characterized in that the first polar face is the (0001) Si polar face of 4H-, 6H- or 15R-SiC or the (111) Si polar face of 3C-SiC, or a face the deviation of which in a plane direction from the (0001) Si polar face or the (111) Si polar face is no larger than 10 degrees.

38. The semiconductor device according to claim 3, characterized in that the first polar face is the (0001) Si polar face of 4H-, 6H- or 15R-SiC or the (111) Si polar face of 3C-SiC, or a face the deviation of which in a plane direction from the (0001) Si polar face or the (111) Si polar face is no larger than 10 degrees.

39. The semiconductor device according to claim 2, characterized in that the first polar face is the (0001) Si polar face of 4H-, 6H- or 15R-SiC or the (111) Si polar face of 3C-SiC, or a face the deviation of which in a plane direction from the (0001) Si polar face or the (111) Si polar face is no larger than 10 degrees.

40. The semiconductor device according to claim 3, characterized in that the first polar face is the (0001) Si polar face of 4H-, 6H- or 15R-SiC or the (111) Si polar face of 3C-SiC, or a face the deviation of which in a plane direction from the (0001) Si polar face or the (111) Si polar face is no larger than 10 degrees.

41. The semiconductor device according to claim 3, characterized in that the first polar face is the (0001) Si polar face of 4H-, 6H- or 15R-SiC or the (111) Si polar face of 3C-SiC, or a face the deviation of which in a plane direction from the (0001) Si polar face or the (111) Si polar face is no larger than 10 degrees, and the second polar face is the (000-1) nitrogen or O (oxygen) polar face of a group III nitride layer or a group II oxide layer, or a face the deviation of which in a plane direction from the (000-1) face is no larger than 10 degrees.

42. The semiconductor device according to claim 3, characterized in that the first polar face is the (000-1) C polar face of 4H-, 6H- or 15R-SiC or the (-1-1-1) Si polar face of 3C-SiC, or a face the deviation of which in a plane direction from the (000-1) C polar face or the (-1-1-1) Si polar face is no larger than 10 degrees, and the second polar face is the (0001) group III or group II polar face of a group III nitride layer or a group II oxide layer, or a face the deviation of which in a plane direction from the (0001) face is no larger than 10 degrees.
